(19) United States
(12) Patent Application Publication
(10) Pub. No.: US 2025/0194426 A1
(43) Pub. Date: Jun. 12, 2025

(54) LIGHT EMITTING DEVICE AND DISPLAY DEVICE

(71) Applicant: SONY GROUP CORPORATION, TOKYO (JP)

(72) Inventors: GO IGARASHI, TOKYO (JP); YOSHIYUKI KURODA, TOKYO (JP); KOYA NOMOTO, TOKYO (JP)

(21) Appl. No.: 18/844,167

(22) PCT Filed: Feb. 7, 2023
(86) PCT No.: PCT/JP2023/003891

§ 371 Date: Sep. 5, 2024

(30) Foreign Application Priority Data
Mar. 16, 2022 (JP) 2022-041154

(51) Int. Cl. H10N 30/20; H05K 5/02; H10H 29/24; H10N 39/00

(52) U.S. Cl. CPC H10N 30/206; H05K 5/0217; H10H 29/24; H10N 39/00

(57) ABSTRACT

A light emitting device (3) according to the present disclosure includes a substrate (10), a frame (20), and an actuator (30). The substrate (10) includes a plurality of light emitting elements (11) arranged on a first surface (10a). The frame (20) is disposed to face a second surface (10b) of the substrate (10) opposite to the first surface (10a). The actuator (30) is disposed between the substrate (10) and the frame (20), and vibrates the substrate (10). In addition, the substrate (10) is configured to be detachable from the actuator (30).

### FIELD

The present disclosure relates to a light emitting device and a display device.

### BACKGROUND

As a large-screen video display system, a scalable display that displays a large-screen video by arranging a plurality of display devices in a matrix has been widely used. Such a scalable display is used, for example, for advertisement display in towns, information provision to spectators at exhibitions, sports facilities, and the like (see, for example, Patent Literature 1).

### CITATION LIST

### Patent Literature

Patent Literature 1: JP 2012-198446 A

### SUMMARY

### Technical Problem

The present disclosure proposes a light emitting device and a display device capable of improving maintainability.

### Solution to Problem

According to the present disclosure, there is provided a light emitting device. The light emitting device includes a substrate, a frame, and an actuator. The substrate includes a plurality of light emitting elements arranged on a first surface. The frame is disposed to face a second surface of the substrate opposite to the first surface. The actuator is disposed between the substrate and the frame, and vibrates the substrate. In addition, the substrate is configured to be detachable from the actuator.

### BRIEF DESCRIPTION OF DRAWINGS

FIG. 1 is a diagram schematically illustrating an example of a configuration of a scalable display according to an embodiment of the present disclosure.

FIG. 2 is a cross-sectional view illustrating an example of a configuration of a cabinet according to the embodiment of the present disclosure.

FIG. 3 is a plan view illustrating an example of a configuration of a substrate according to the embodiment of the present disclosure.

FIG. 4 is a plan view illustrating an example of a configuration of a frame and an arrangement of a plurality of actuators according to the embodiment of the present disclosure.

FIG. 5 is a cross-sectional view illustrating an example of a configuration of the actuator according to the embodiment of the present disclosure.

FIG. 6 is an enlarged cross-sectional view illustrating an example of a configuration of the substrate according to the embodiment of the present disclosure.

FIG. 7 is a diagram illustrating a relationship between a frequency and a sound pressure in a light emitting device according to the embodiment of the present disclosure.

FIG. 8 is a diagram illustrating a vibration phase distribution in the light emitting device according to the embodiment of the present disclosure.

FIG. 9 is a diagram illustrating a vibration phase distribution in the light emitting device according to the embodiment of the present disclosure.

FIG. 10 is a diagram illustrating a vibration phase distribution in the light emitting device according to the embodiment of the present disclosure.

FIG. 11 is a diagram illustrating a vibration phase distribution in the light emitting device according to the embodiment of the present disclosure.

FIG. 12 is a diagram illustrating a vibration phase distribution in the light emitting device according to the embodiment of the present disclosure.

FIG. 13 is a cross-sectional view illustrating an example of a configuration of an actuator according to Modification 1 of the embodiment of the present disclosure.

FIG. 14 is a cross-sectional view illustrating an example of a configuration of a cabinet according to Modification 2 of the embodiment of the present disclosure.

### DESCRIPTION OF EMBODIMENTS

Hereinafter, embodiments of the present disclosure will be described with reference to the accompanying drawings. Note that the present disclosure is not limited to the following embodiments. In addition, the embodiments can be appropriately combined within a range in which the processing contents do not contradict each other. In addition, in the following embodiments, the same parts are denoted by the same reference numerals, and redundant description will be omitted.

In addition, in the embodiments described below, expressions such as “constant”, “orthogonal”, “vertical”, or “parallel” may be used, but these expressions do not need to be strictly “constant”, “orthogonal”, “vertical”, or “parallel”. That is, it is assumed that each expression described above allows deviation in manufacturing accuracy, installation accuracy, and the like, for example.

As a large-screen video display system, a scalable display that displays a large-screen video by arranging a plurality of display devices in a matrix has been widely used. Such a scalable display is used, for example, for advertisement display in towns, information provision to spectators at exhibitions, sports facilities, and the like.

On the other hand, in the above-described conventional technique, in a case where a defect such as non-lighting or always-on lighting occurs in a small display device constituting the scalable display, it is necessary to replace the entire small display device. That is, in the above-described conventional technique, there is room for improvement in maintainability of the scalable display.

Therefore, it is expected to realize a technique capable of overcoming the above-described problem and improving maintainability of the scalable display.

### [Configuration of Scalable Display]

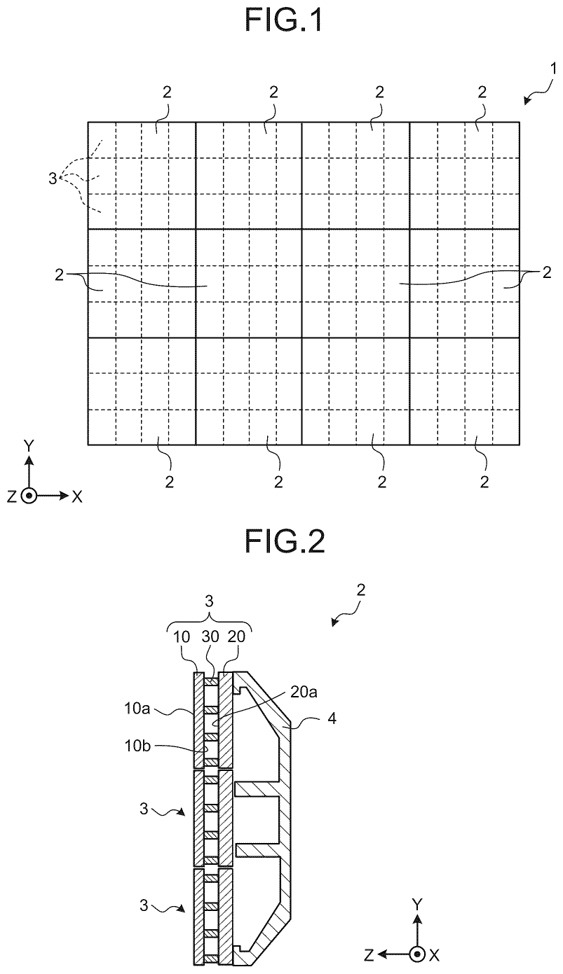

First, a configuration of a scalable display 1 according to an embodiment will be described with reference to FIG. 1. FIG. 1 is a diagram schematically illustrating an example of the configuration of the scalable display 1 according to the embodiment of the present disclosure. The scalable display 1 is an example of a display device.

The scalable display 1 includes a plurality of cabinets 2. In the scalable display 1, the plurality of cabinets 2 are arranged in a matrix. For example, in the example of FIG. 1, 12 cabinets 2 are arranged in three rows and four columns in one scalable display 1.

Note that in each of the following drawings, an X-axis direction, a Y-axis direction, and a Z-axis direction orthogonal to each other are defined for easy understanding of the description. In addition, in this orthogonal coordinate system, a Z-axis positive direction is a direction in which a screen of the scalable display 1 faces, a Y-axis positive direction is a vertically upward direction, and the X-axis direction is a direction orthogonal to the Y-axis and the Z-axis (that is, the horizontal direction of the screen in the scalable display 1).

The cabinet 2 includes a plurality of light emitting devices 3. In the cabinet 2, the plurality of light emitting devices 3 are arranged in a matrix. For example, in the example of FIG. 1, 12 light emitting devices 3 are arranged in three rows and four columns in one cabinet 2.

The light emitting device 3 includes a plurality of light emitting elements 11 (see FIG. 6). In the light emitting device 3, the plurality of light emitting elements 11 are arranged in a matrix. The light emitting element 11 is, for example, a light emitting diode (LED) element, and can emit light by individually controlling light of a plurality of colors (for example, three colors of RGB). That is, the light emitting element 11 can emit light of a desired color.

As described above, in the light emitting device 3 according to the embodiment, since the plurality of light emitting elements 11 that emit light of desired colors are arranged in a matrix, the light emitting device 3 can display a desired color video having a small area.

Then, since a large number of the light emitting devices 3 are arranged in a matrix in the scalable display 1 according to the embodiment, the scalable display 1 can display a desired color video having a large area obtained by combining images displayed on the plurality of light emitting devices 3.

Note that in the above example, a case where the light emitting element 11 can emit light of a desired color has been described, but the present disclosure is not limited, and for example, the light emitting element 11 may emit a given monochromatic light (for example, white light).

In addition, in the above example, an example in which the light emitting element 11 is an LED element has been described, but the present disclosure is not limited to such an example, and for example, the light emitting element 11 may be a light emitting element (for example, a laser diode (LD) element, an organic electro-luminescence (EL) element, or the like) other than the LED element.

In addition, the number of cabinets 2 and the number of light emitting devices 3 arranged in the scalable display 1 are not limited to those in the example of FIG. 1, and a desired number of cabinets 2 and a desired number of light emitting devices 3 can be arranged.

### [Configuration of Cabinet]

Next, configurations of the cabinet 2 and the light emitting device 3 according to the embodiment will be described with reference to FIG. 2. FIG. 2 is a cross-sectional view illustrating an example of the configuration of the cabinet 2 according to the embodiment of the present disclosure.

As illustrated in FIG. 2, the cabinet 2 includes the plurality of light emitting devices 3 and a support 4. The support 4 is disposed on the Z-axis negative direction side with respect to the plurality of light emitting devices 3 arranged on an XY plane, and collectively supports the plurality of light emitting devices 3.

In addition, the light emitting device 3 includes a substrate 10, a frame 20, and a plurality of actuators 30. The substrate 10 is, for example, a plate-like circuit board, and has a first surface 10a and a second surface 10b.

The first surface 10a is a main surface of the substrate 10 facing in the Z-axis positive direction. The plurality of light emitting elements 11 (see FIG. 6) are arranged on the first surface 10a. In addition, the second surface 10b is a main surface of the substrate 10 facing in the Z-axis negative direction.

The frame 20 is, for example, a plate-like metal plate, and is disposed to face the second surface 10b of the substrate 10. A first surface 20a which is one main surface of the frame 20 is disposed substantially parallel to the second surface 20b of the substrate 10.

The plurality of actuators 30 are disposed between the substrate 10 and the frame 20. The plurality of actuators 30 vibrate the substrate 10 in the Z-axis direction. Then, by driving the plurality of actuators 30 by an audio signal, the light emitting device 3 also functions as a speaker that generates a desired sound from the substrate 10 toward the Z-axis positive direction.

That is, the scalable display 1 according to the embodiment can generate desired sounds individually from all the light emitting devices 3 arranged in a matrix toward the front of the scalable display 1.

As a result, a sound image can be accurately localized in the screen as compared with a case where the sound is generated from a speaker arranged along the edge of the scalable display 1. Therefore, according to the embodiment, it is possible to reproduce the sense of unity between a video and audio in the scalable display 1 having a large screen. [Details of Light Emitting Device]

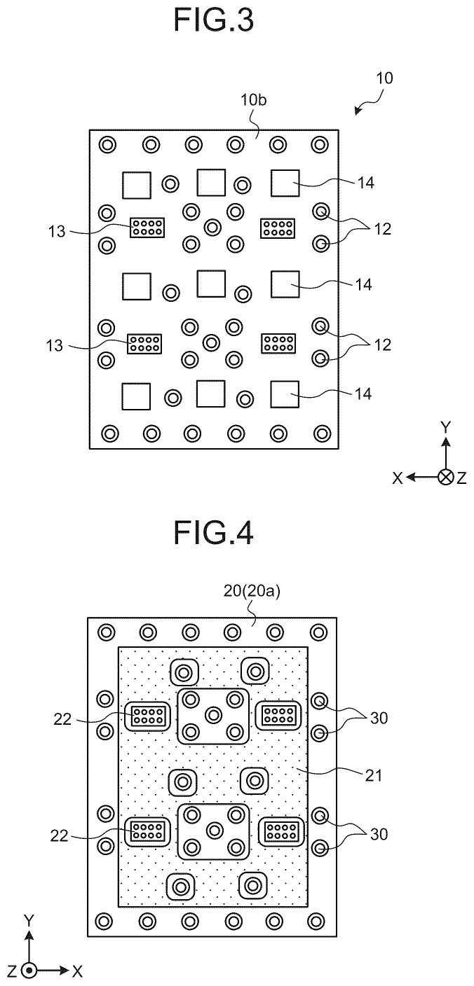

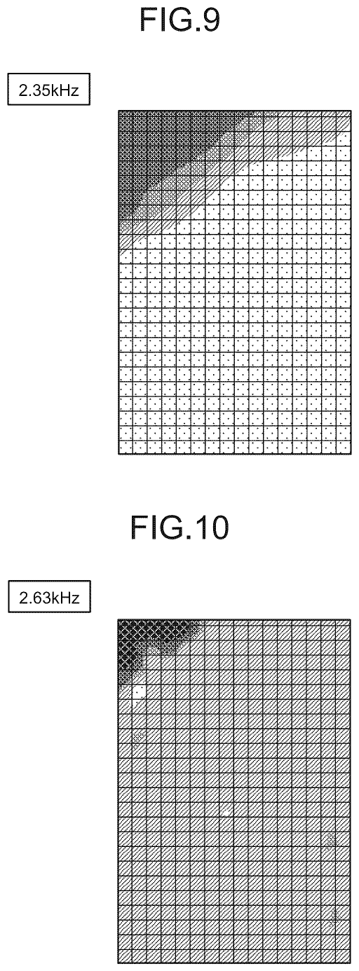

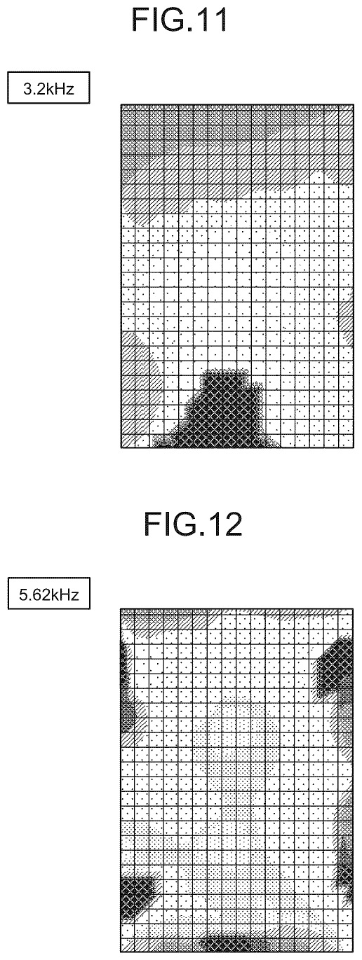

Next, a detailed configuration of the light emitting device 3 according to the embodiment will be described with reference to FIGS. 3 to 13. FIG. 3 is a plan view illustrating an example of a configuration of the substrate 10 according to the embodiment of the present disclosure, and is a diagram when the substrate 10 is viewed from the Z-axis negative direction side.

As illustrated in FIG. 3, a plurality of panel holders 12, a plurality of terminals 13, and a plurality of control integrated circuits (ICs) 14 are provided on the second surface 10b of the substrate 10.

The plurality of panel holders 12 are joined to the second surface 10b of the substrate 10, and are provided at positions corresponding to the plurality of actuators 30 (see FIG. 4) located on the first surface 20a (see FIG. 4) of the frame 20 (see FIG. 4).

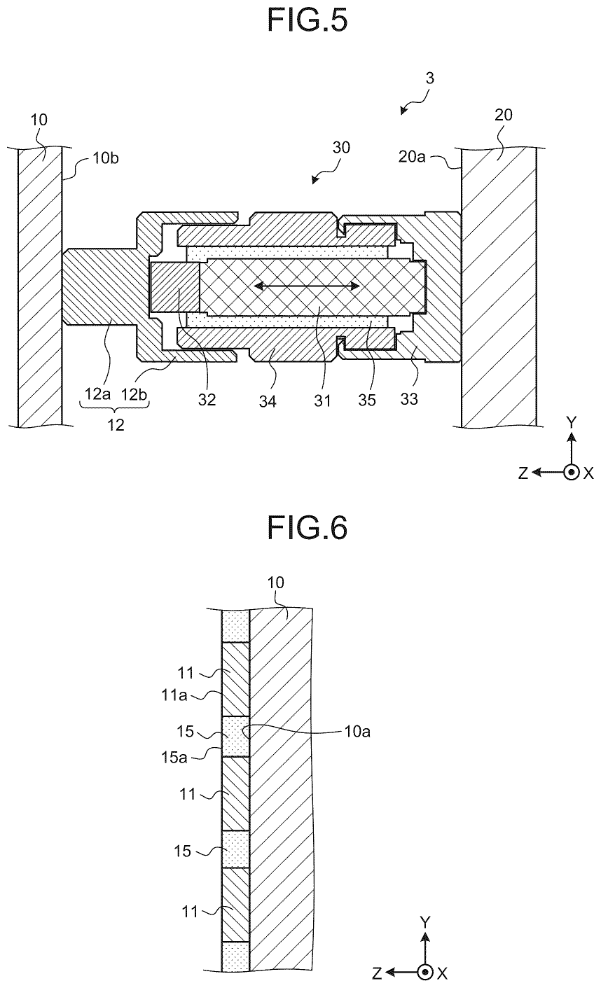

Then, the panel holder 12 comes into contact with a magnet 32 (see FIG. 5) located at a tip end portion of the actuator 30. As a result, the panel holder 12 transmits a vibration force generated by the actuator 30 to the substrate 10. In addition, the panel holder 12 is made of a soft magnetic material (for example, an iron-based material or the like).

The plurality of terminals 13 are disposed so as to extend in the Z-axis negative direction, and are provided at positions corresponding to a plurality of spring contact terminals 22 (see FIG. 4) located on the first surface 20a of the frame 20.

Then, the terminal 13 comes into contact with a tip end portion of the spring contact terminal 22. As a result, the substrate 10 transmits power and various control signals to the plurality of light emitting elements 11 (see FIG. 6), the plurality of control ICs 14, and the like via the spring contact terminals 22 and the terminals 13.

The control IC 14 controls the light emitting element 11 disposed on the first surface 10a of the substrate 10. Note that although not illustrated in FIG. 3, a passive element or the like may be provided on the second surface 10b of the substrate 10.

FIG. 4 is a plan view illustrating an example of a configuration of the frame 20 and an arrangement of the plurality of actuators 30 according to the embodiment of the present disclosure, and is a diagram when the frame 20 is viewed from the Z-axis positive direction side. That is, the first surface 20a of the frame 20 illustrated in FIG. 4 is a surface facing the second surface 10b of the substrate 10 illustrated in FIG. 3.

As illustrated in FIG. 4, a substrate 21, the plurality of spring contact terminals 22, and the plurality of actuators 30 are provided on the first surface 20a of the frame 20.

The substrate 21 transmits power and various control signals to the plurality of actuators 30 and the like. The plurality of spring contact terminals 22 are bent in a push-in direction by the terminals 13 (see FIG. 3) that come into contact with the spring contact terminals so as to push the spring contact terminals in the Z-axis negative direction. As a result, in the embodiment, the terminal 13 and the spring contact terminal 22 can be stably brought into contact with each other.

The plurality of actuators 30 are joined to the first surface 20a of the frame 20. The plurality of actuators 30 are disposed so as to be substantially evenly distributed over the entire substrate 10 (see FIG. 3) with which the actuators come into contact, except for portions where the actuators cannot be disposed (for example, portions where the terminal 13, the control IC 14 (see FIG. 3), and the like are disposed).

In addition, in the embodiment, as illustrated in FIG. 4, the substrate 21 may be disposed so as to avoid all the actuators 30. As a result, the tip end portions of all the actuators 30 are substantially flush, so that all the actuators 30 can come into contact with the substrate 10 without rattling.

FIG. 5 is a cross-sectional view illustrating an example of a configuration of the actuator 30 according to the embodiment of the present disclosure. Note that FIG. 5 also illustrates the substrate 10, the panel holder 12, and the frame 20 located in the vicinity of the actuator 30.

As illustrated in FIG. 5, the actuator 30 includes a piezoelectric element 31, the magnet 32, a piezoelectric holder 33, a guide shaft 34, and a soft resin 35.

The piezoelectric element 31 expands and contracts along the Z-axis direction in response to an audio signal supplied from a control device (not illustrated) of the scalable display 1. As a result, the piezoelectric element 31 generates a vibration force for vibrating the substrate 10 along the Z-axis direction.

The piezoelectric element 31 is configured by, for example, alternately stacking a piezoelectric layer and an electrode layer along the Z-axis direction, and has a columnar shape extending along the Z-axis direction.

The magnet 32 is joined to a tip end portion of the piezoelectric element 31 (that is, on the Z-axis positive direction side of the piezoelectric element 31). An end of the magnet 32 on the Z-axis positive direction side has a planar shape substantially parallel to the XY plane.

The piezoelectric holder 33 has an end portion on the Z-axis negative direction side joined to the frame 20, and supports the piezoelectric element 31 on the Z-axis positive direction side. As a result, the piezoelectric holder 33 fixes the piezoelectric element 31 to the frame 20. The piezoelectric holder 33 has, for example, a cylindrical shape in which the end portion on the Z-axis negative direction side is closed, and supports the piezoelectric element 31 on an inner bottom surface in the cylindrical shape.

The guide shaft 34 having a tubular shape is fixed to the piezoelectric holder 33 and houses the piezoelectric element 31 having a columnar shape. The guide shaft 34 has, for example, a cylindrical shape, and is fixed to the piezoelectric holder 33 by fitting an end portion on the Z-axis negative direction side with an end portion of the piezoelectric holder 33 on the Z-axis positive direction side.

The guide shaft 34 is made of, for example, a resin material (for example, polyacetal (POM), polytetrafluoroethylene (PTFE), and the like) having a low friction coefficient.

The soft resin 35 is disposed between the piezoelectric element 31 and the guide shaft 34, and is in contact with both the piezoelectric element 31 and the guide shaft 34. The soft resin 35 has, for example, a hardness (Rockwell hardness) of 40 or less. Note that the soft resin 35 may be in contact with at least one of the magnet 32 and the piezoelectric holder 33.

In addition, the magnet 32 projects from the guide shaft 34 at an end of the actuator 30 on the Z-axis positive direction side.

The panel holder 12 that comes into contact with the actuator 30 described above has a base end portion 12a and a tip end portion 12b. The base end portion 12a is located on the Z-axis positive direction side in the panel holder 12, and has a columnar shape extending along the Z-axis direction. An end of the base end portion 12a on the Z-axis positive direction side is joined to the substrate 10.

The tip end portion 12b is located on the Z-axis negative direction side in the panel holder 12, and has a cylindrical shape extending along the Z-axis direction. The tip end portion 12b is slidably supported along the Z-axis direction with respect to the guide shaft 34.

For example, in the embodiment, the inner diameter of the tip end portion 12b is formed to be slightly larger than the outer diameter of the guide shaft 34, and an inner wall of the tip end portion 12b and an outer wall of the guide shaft 34 are disposed to face each other. As a result, the panel holder 12 is slidably supported along the Z-axis direction with respect to the guide shaft 34.

Here, in the embodiment, the substrate 10 is supported by the actuator 30 by a magnetic force acting between the magnet 32 of the actuator 30 and the panel holder 12, and the terminal 13 (see FIG. 3) of the substrate 10 is electrically connected to the spring contact terminal 22 which is extendable.

That is, in the embodiment, since the substrate 10 and the actuator 30 are not fixed to each other by an adhesive or the like, the substrate 10 can be easily removed from the actuator 30 and the frame 20 only by pulling the substrate toward the Z-axis positive direction.

As a result, when a defect occurs in the light emitting element 11 (see FIG. 6) mounted on the substrate 10, only the substrate 10 in which the defect occurs can be removed and replaced with a normal substrate 10. Therefore, according to the embodiment, maintainability of the scalable display 1 can be improved.

In addition, in the embodiment, since the actuator 30 and the panel holder 12 are in rigid contact with each other by a magnetic force, the vibration force of the actuator 30 can be accurately transmitted to the substrate 10 as compared with a case where the actuator 30 and the panel holder 12 are in contact with each other via an adhesive or the like.

Therefore, according to the embodiment, the sound quality of the light emitting device 3 also functioning as a speaker can be improved.

Note that in this embodiment, an example in which the substrate 10 is configured to be detachable from the actuator 30 using the magnetic force of the magnet 32 has been described, but the present disclosure is not limited to such an example, and the substrate 10 may be supported using another detachable means.

In addition, in the embodiment, the panel holder 12 is preferably slidably supported with respect to the guide shaft 34 of the actuator 30. As a result, stress applied to the substrate 10 and the panel holder 12 along the XY plane can be received by the guide shaft 34 and the piezoelectric holder 33.

That is, in the embodiment, it is possible to suppress transmission of the stress applied to the substrate 10 and the panel holder 12 along the XY plane to the piezoelectric element 31. Therefore, according to the embodiment, it is possible to suppress the damage of the piezoelectric element 31 which is easily damaged by the stress along the XY plane, and thus, it is possible to improve the reliability of the light emitting device 3.

In addition, in the embodiment, the guide shaft 34 is preferably made of a resin material having a low friction coefficient. As a result, the panel holder 12 can easily slide with respect to the guide shaft 34, so that the vibration force of the actuator 30 can more accurately be transmitted to the substrate 10.

Therefore, according to the embodiment, the sound quality of the light emitting device 3 also functioning as a speaker can be further improved.

In addition, in the embodiment, the actuator 30 preferably includes the soft resin 35 disposed between the piezoelectric element 31 and the guide shaft 34. As a result, heat generated from the piezoelectric element 31 during the operation of the piezoelectric element 31 can be transmitted to the guide shaft 34 via the soft resin 35.

That is, in the embodiment, since the heat dissipation of the piezoelectric element 31 can be improved, the reliability of the light emitting device 3 can be improved.

In addition, in the embodiment, as illustrated in FIG. 5, the base end portion 12a of the panel holder 12 is preferably narrower than the tip end portion 12b of the panel holder 12. As described above, by narrowing the base end portion 12a of the panel holder 12, the occupied area of the panel holder 12 in the second surface 10b of the substrate 10 can be reduced.

Therefore, according to the embodiment, since more other components (for example, the control IC 14, the passive element, and the like) can be mounted on the second surface 10b of the substrate 10, the function of the light emitting device 3 can be enhanced.

In addition, in the embodiment, all the actuators 30 disposed between the substrate 10 and the frame 20 are preferably driven in phase. As a result, the entire surface of the substrate 10 can be driven substantially uniformly in phase as compared with a case where the substrate 10 is driven by one actuator 30.

This is because, when the substrate 10 is driven by one actuator 30, a portion of the substrate 10 away from the actuator 30 bends and moves in the opposite direction, so that the phase is shifted at such a portion.

On the other hand, in the embodiment, by driving all the plurality of actuators 30 in phase, the entire surface of the substrate 10 can be driven substantially uniformly in phase, so that the sound quality of the light emitting device 3 also functioning as a speaker can be further improved.

In addition, in the embodiment, since the entire surface of the substrate 10 can be substantially uniformly driven in phase, various types of signal processing can be easily performed. For example, in the embodiment, since phase interference can be caused by inputting different audio signals to a plurality of the substrates 10, a sound can have directivity in a direction different from the Z-axis positive direction.

FIG. 6 is an enlarged cross-sectional view illustrating an example of a configuration of the substrate 10 according to the embodiment of the present disclosure. As illustrated in FIG. 6, in the embodiment, the substrate 10 includes a resin 15 disposed between the light emitting elements 11 adjacent to each other on the first surface 10a.

Then, in the embodiment, a surface 11a of the light emitting element 11 and a surface 15a of the resin 15 are preferably substantially flush with each other. As a result, since all places (that is, contact portions between the substrate 10 and air) where sound waves are generated by the vibration of the substrate 10 can be made substantially flush, phases can be more easily aligned on the entire surface of the substrate 10.

Therefore, according to the embodiment, the sound quality of the light emitting device 3 also functioning as a speaker can be further improved.

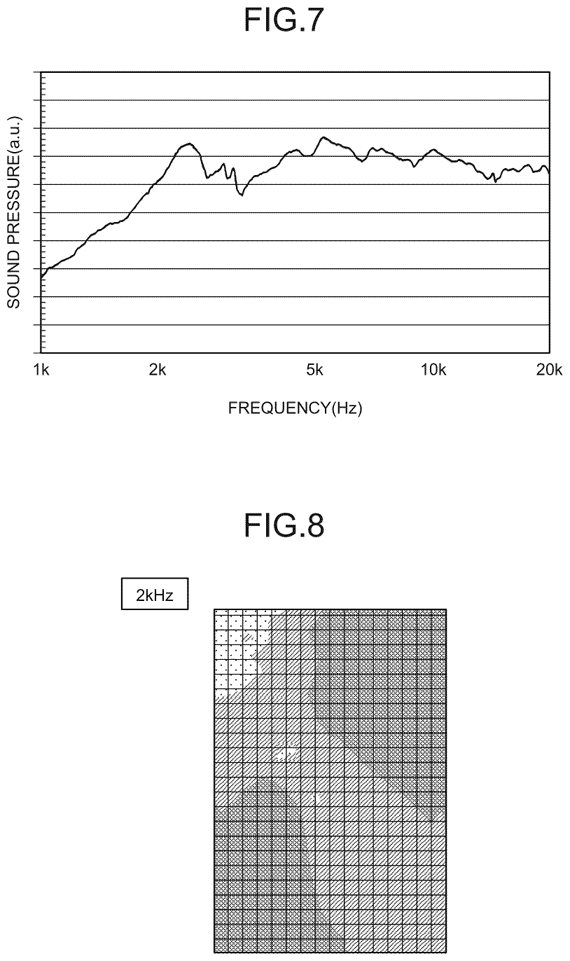

FIG. 7 is a diagram illustrating a relationship between a frequency and a sound pressure in the light emitting device 3 according to the embodiment of the present disclosure, and FIGS. 8 to 12 are diagrams illustrating vibration phase distributions in the light emitting device 3 according to the embodiment of the present disclosure. Note that FIGS. 7 to 12 illustrate results in a case where one substrate 10 is vibrated by 36 actuators 30 driven in phase as illustrated in FIGS. 3 and 4.

As illustrated in FIG. 7, in the embodiment, a substantially uniform sound pressure can be output in a frequency band of 4 (kHz) to 8 (kHz) that affects localization of a sound image. In addition, as illustrated in FIGS. 8 to 12, in the embodiment, the entire surface of the substrate 10 can be driven substantially uniformly in phase in a frequency band of 2 (kHz) to 5.62 (kHz).

In addition, in the embodiment, a sound absorbing material may be disposed between the substrate 10 and the frame 20. As a result, it is possible to suppress emission of an opposite-phase sound emitted from the second surface 10b of the substrate 10 to the outside. Therefore, according to the embodiment, the sound quality of the light emitting device 3 also functioning as a speaker can be further improved.

### Various Modifications

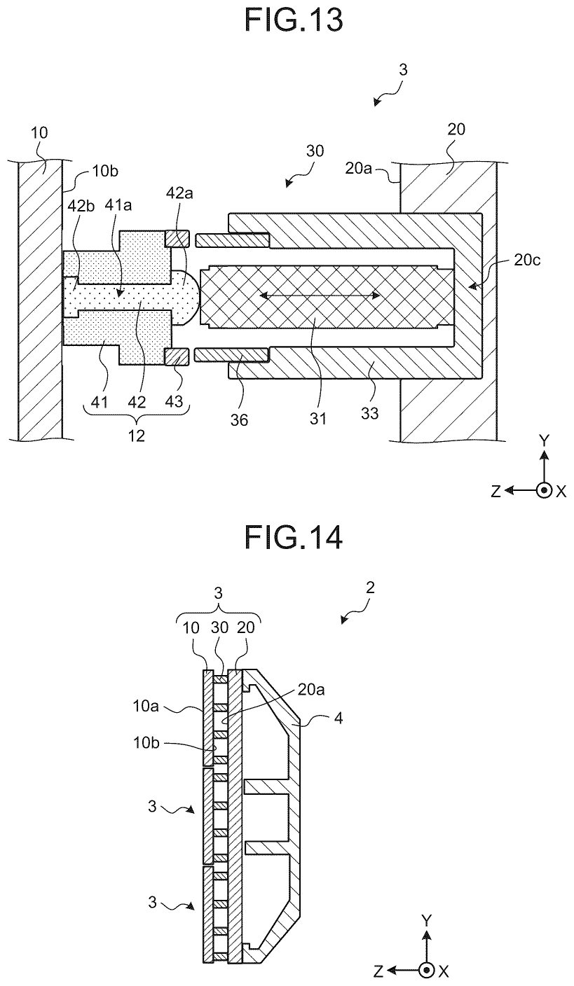

Next, various modifications of the embodiment will be described with reference to FIGS. 13 and 14. FIG. 13 is a cross-sectional view illustrating an example of a configuration of the actuator 30 according to Modification 1 of the embodiment of the present disclosure. Note that FIG. 13 also illustrates the substrate 10, the panel holder 12, and the frame 20 located in the vicinity of the actuator 30.

As illustrated in FIG. 13, the actuator 30 of Modification 1 includes the piezoelectric element 31, the piezoelectric holder 33, and a soft magnetic material 36.

The piezoelectric element 31 expands and contracts along the Z-axis direction in response to an audio signal supplied from a control device (not illustrated) of the scalable display 1. As a result, the piezoelectric element 31 generates a vibration force for vibrating the substrate 10 along the Z-axis direction.

The piezoelectric element 31 is configured by, for example, alternately stacking a piezoelectric layer and an electrode layer along the Z-axis direction, and has a columnar shape extending along the Z-axis direction.

The piezoelectric holder 33 is joined such that the end portion on the Z-axis negative direction side fits into a recess 20c formed in the first surface 20a of the frame 20, and supports the piezoelectric element 31 on the Z-axis positive direction.

As a result, the piezoelectric holder 33 fixes the piezoelectric element 31 to the frame 20. The piezoelectric holder 33 has, for example, a cylindrical shape in which the end portion on the Z-axis negative direction side is closed, and supports the piezoelectric element 31 on an inner bottom surface in the cylindrical shape.

The soft magnetic material 36 having a tubular shape is fixed to the piezoelectric holder 33 and houses the piezoelectric element 31 having a columnar shape. The guide shaft 34 has, for example, a cylindrical shape, and is fixed to the piezoelectric holder 33 by fitting an end portion on the Z-axis negative direction side with an end portion of the piezoelectric holder 33 on the Z-axis positive direction side. The soft magnetic material 36 is made of, for example, an iron-based material.

The panel holder 12 that comes into contact with the actuator 30 described above includes a first portion 41, a second portion 42, and a magnet 43. The first portion 41 has a tubular shape extending along the Z-axis direction.

The second portion 42 has a columnar shape extending along the Z-axis direction, and is disposed so as to be fitted in a space 41a formed inside the first portion 41. An abutting portion 42a that abuts on the tip end portion of the piezoelectric element 31 in the actuator 30 is provided on a tip end side (that is, on the Z-axis negative direction side) of the second portion 42. The abutting portion 42a has, for example, a hemispherical shape.

The first portion 41 and the second portion 42 are made of, for example, a resin. Ends of the first portion 41 and the second portion 42 on the Z-axis positive direction side are joined to the substrate 10.

In addition, in the second portion 42, the abutting portion 42a on the tip end side and a base end portion 42b are larger in diameter than the other portion. As a result, it is possible to suppress coming off of the second portion 42 from the first portion 41.

The magnet 43 has, for example, a tubular shape, and is joined to a tip end portion of the first portion 41 (that is, on the Z-axis negative direction side of the first portion 41). The magnet 43 has a diameter substantially equal to that of the soft magnetic material 36 of the actuator 30.

Here, in Modification 1, the substrate 10 is supported by the actuator 30 by a magnetic force acting between the soft magnetic material 36 of the actuator 30 and the magnet 43 of the panel holder 12. In addition, in Modification 1, as in the above-described embodiment, the terminal 13 (see FIG. 3) of the substrate 10 is electrically connected to the spring contact terminal 22 which is extendable.

That is, in Modification 1, since the substrate 10 and the actuator 30 are not fixed to each other by an adhesive or the like, the substrate 10 can be easily removed from the actuator 30 and the frame 20 only by pulling the substrate toward the Z-axis positive direction side.

As a result, when a defect occurs in the light emitting element 11 (see FIG. 6) mounted on the substrate 10, only the substrate 10 in which the defect occurs can be removed and replaced with a normal substrate 10. Therefore, according to Modification 1, maintainability of the scalable display 1 can be improved.

In addition, in Modification 1, since the actuator 30 and the panel holder 12 are in rigid contact with each other by the magnetic force, the vibration force of the actuator 30 can be accurately transmitted to the substrate 10 as compared with a case where the actuator 30 and the panel holder 12 are in contact with each other via an adhesive or the like.

Therefore, according to Modification 1, the sound quality of the light emitting device 3 also functioning as a speaker can be improved.

In addition, in Modification 1, since the tip end portion of the piezoelectric element 31 is in contact with the abutting portion 42a but is not fixed to the abutting portion 42a, it is possible to suppress application of extra stress to the piezoelectric element 31 when only the substrate 10 in which a defect occurs is removed and replaced with a normal substrate 10.

Therefore, according to Modification 1, since the damage of the piezoelectric element 31 can be suppressed, the reliability of the light emitting device 3 also functioning as a speaker can be improved.

In addition, in Modification 1, the abutting portion 42a of the panel holder 12 is preferably made of a resin. As a result, the abutting portion 42a can be brought into contact with the piezoelectric element 31 so as to be crushed, so that even if the abutting portions 42a of all the panel holders 12 are not completely flush, all the abutting portions 42a can be brought into contact with the piezoelectric elements 31 without any problem.

Therefore, according to Modification 1, the sound quality of the light emitting device 3 also functioning as a speaker can be further improved. Note that in the present disclosure, an example in which the first portion 41 and the second portion 42 are all made of a resin has been described, but the present disclosure is not limited to such an example, and a portion other than the abutting portion 42a may be made of a material different from the resin.

On the other hand, when at least the entire second portion 42 is integrally formed of a resin, it is possible to suppress peeling of the abutting portion 42a from other portions in operating the light emitting device 3 as a speaker. Therefore, according to Modification 1, the reliability of the light emitting device 3 also functioning as a speaker can be improved.

In addition, in Modification 1, the abutting portion 42a preferably has a hemispherical shape. As a result, since the contact area between the piezoelectric element 31 and the abutting portion 42a can be reduced, it is possible to suppress the damage of the piezoelectric element 31 due to friction or the like between the piezoelectric element 31 and the abutting portion 42a.

Therefore, according to Modification 1, the reliability of the light emitting device 3 also functioning as a speaker can be improved.

In addition, in Modification 1, since the abutting portion 42a has a hemispherical shape, the contact area between the piezoelectric element 31 and the abutting portion 42a can be maintained to be substantially the same area even if the substrate 10 is disposed to be inclined with respect to the frame 20.

Therefore, according to Modification 1, even if the substrate 10 is disposed to be inclined with respect to the frame 20, the sound quality of the light emitting device 3 also functioning as a speaker can be favorably maintained.

In addition, in Modification 1, the piezoelectric holder 33 of the actuator 30 is preferably disposed so as to be embedded in the recess 20c of the frame 20. As a result, since a projecting length of the actuator 30 can be shortened, the thickness of the light emitting device 3 can be reduced.

In addition, in Modification 1, a base end portion of the first portion 41 is preferably narrower than the tip end portion of the first portion 41. As described above, by narrowing the base end portion of the first portion 41, the occupied area of the panel holder 12 in the second surface 10b of the substrate 10 can be reduced.

Therefore, according to Modification 1, since more other components (for example, the control IC 14, the passive element, and the like) can be mounted on the second surface 10b of the substrate 10, the function of the light emitting device 3 can be enhanced.

Note that in the example of FIG. 13, an example in which the soft magnetic material 36 is provided in the actuator 30 and the magnet 43 is provided in the panel holder 12 has been described, but the present disclosure is not limited to such an example. For example, the actuator 30 may be provided with a tubular magnet, the panel holder 12 may be provided with a tubular soft magnetic material, or both the actuator 30 and the panel holder 12 may be provided with a tubular magnet.

Also with this configuration, since the substrate 10 can be easily removed from the actuator 30 and the frame 20 only by pulling the substrate toward the Z-axis positive direction side, maintainability of the scalable display 1 can be improved.

FIG. 14 is a cross-sectional view illustrating an example of a configuration of the cabinet 2 according to Modification 2 of the embodiment of the present disclosure. In the example of FIG. 2 described above, an example in which the substrate 10 and the frame 20 are provided on a one-to-one basis has been described, but the present disclosure is not limited to such an example.

As illustrated in FIG. 14, in Modification 2, one frame 20 is provided for a plurality of the substrates 10. In Modification 2, for example, one common frame 20 is provided for the plurality of (three in the drawing) substrates 10 arranged in a row in the Y-axis direction in one cabinet 2.

Even with such a configuration, since the substrate 10 can be configured to be detachable from the frame 20, maintainability of the scalable display 1 can be improved.

In addition, in the above embodiment, an example in which the piezoelectric holder 33, the guide shaft 34, and the tip end portion 12b of the panel holder 12 have a cylindrical shape has been described, but the present disclosure is not limited to such an example. For example, the piezoelectric holder 33, the guide shaft 34, and the tip end portion 12b of the panel holder 12 may have a polygonal tubular shape or the like.

On the other hand, in the embodiment, by forming the piezoelectric holder 33, the guide shaft 34, and the tip end portion 12b of the panel holder 12 into a cylindrical shape, the respective members can be supported without accurately adjusting the directions of these members. Therefore, according to the embodiment, the light emitting device 3 can be easily manufactured.

### Effects

The light emitting device 3 according to the embodiment includes the substrate 10, the frame 20, and the actuator 30. The substrate 10 includes the plurality of light emitting elements 11 arranged on the first surface 10a. The frame 20 is disposed to face the second surface 10b of the substrate 10 opposite to the first surface 10a. The actuator 30 is disposed between the substrate 10 and the frame 20, and vibrates the substrate 10. In addition, the substrate 10 is configured to be detachable from the actuator 30.

As a result, maintainability of the scalable display 1 can be improved.

In addition, in the light emitting device 3 according to the embodiment, the actuator 30 includes the magnet 32 at the tip end portion. In addition, the substrate 10 includes, on the second surface 10b, the panel holder 12 made of a soft magnetic material in contact with the magnet 32, and is supported by the actuator 30 by a magnetic force acting between the magnet 32 and the panel holder 12.

As a result, maintainability of the scalable display 1 can be improved, and the sound quality of the light emitting device 3 also functioning as a speaker can be improved.

In addition, in the light emitting device 3 according to the embodiment, the actuator 30 includes the piezoelectric element 31, the piezoelectric holder 33, and the guide shaft 34. The piezoelectric element 31 has a columnar shape and generates a vibration force. The piezoelectric holder 33 fixes the piezoelectric element 31 to the frame 20. The guide shaft 34 has a tubular shape, is fixed to the piezoelectric holder 33, and houses the piezoelectric element 31. In addition, the panel holder 12 is slidably supported with respect to the guide shaft 34.

As a result, the reliability of the light emitting device 3 can be improved.

In addition, in the light emitting device 3 according to the embodiment, the actuator 30 includes the soft resin 35 disposed between the piezoelectric element 31 and the guide shaft 34.

As a result, the reliability of the light emitting device 3 can be improved.

In addition, in the light emitting device 3 according to the embodiment, the base end portion 12a of the panel holder 12 is narrower than the tip end portion 12b of the panel holder 12.

As a result, the function of the light emitting device 3 can be enhanced.

In addition, in the light emitting device 3 according to the embodiment, the actuator 30 includes the soft magnetic material 36 at the tip end portion. In addition, the substrate 10 includes the panel holder 12 in which the magnet 43 is disposed at the tip end portion, and is supported by the actuator 30 by the magnetic force acting between the magnet 43 and the soft magnetic material 36.

As a result, maintainability of the scalable display 1 can be improved, and the sound quality of the light emitting device 3 also functioning as a speaker can be improved.

In addition, in the light emitting device 3 according to the embodiment, the actuator 30 includes the piezoelectric element 31 having a columnar shape and generating a vibration force. In addition, the abutting portion 42a made of a resin and abutting on the piezoelectric element 31 is provided at a position different from the magnet 43 in the tip end portion of the panel holder 12.

As a result, the sound quality of the light emitting device 3 also functioning as a speaker can be further improved.

In addition, in the light emitting device 3 according to the embodiment, the abutting portion 42a has a hemispherical shape.

As a result, the reliability of the light emitting device 3 also functioning as a speaker can be improved.

In addition, in the light emitting device 3 according to the embodiment, the substrate 10 includes the resin 15 disposed between the light emitting elements 11 adjacent to each other on the first surface 10a, and the surface 11a of the light emitting element 11 and the surface 15a of the resin are substantially flush with each other.

As a result, the sound quality of the light emitting device 3 also functioning as a speaker can be further improved.

In addition, in the light emitting device 3 according to the embodiment, the plurality of actuators 30 are provided between the substrate 10 and the frame 20, and all the actuators 30 are driven in phase.

As a result, the sound quality of the light emitting device 3 also functioning as a speaker can be further improved.

In addition, in the display device (scalable display 1) according to the embodiment, the plurality of light emitting devices 3 are arranged in a matrix. In addition, the light emitting device 3 includes the substrate 10, the frame 20, and the actuator 30. The substrate 10 includes the plurality of light emitting elements 11 arranged on the first surface 10a. The frame 20 is disposed to face the second surface 10b of the substrate 10 opposite to the first surface 10a. The actuator 30 is disposed between the substrate 10 and the frame 20, and vibrates the substrate 10. In addition, the substrate 10 is configured to be detachable from the actuator 30.

As a result, maintainability of the scalable display 1 can be improved.

Although the embodiments of the present disclosure have been described above, the technical scope of the present disclosure is not limited to the above-described embodiments as they are, and various modifications can be made without departing from the gist of the present disclosure. In addition, components of different embodiments and modifications may be appropriately combined.

In addition, the effects described in the present specification are merely examples and are not limited, and other effects may be provided.

Note that the present technology can also have the following configurations.

(1)

A light emitting device comprising:
a substrate including a plurality of light emitting elements arranged on a first surface;
a frame disposed to face a second surface of the substrate opposite to the first surface; and
an actuator disposed between the substrate and the frame and vibrating the substrate, wherein
the substrate is configured to be detachable from the actuator.

(2)

The light emitting device according to the above (1), wherein
the actuator includes a magnet at a tip end portion, and
the substrate includes, on the second surface, a panel holder of a soft magnetic material in contact with the magnet, and is supported by the actuator by a magnetic force acting between the magnet and the panel holder.

(3)

The light emitting device according to the above (2), wherein
the actuator includes
a piezoelectric element having a columnar shape and generating a vibration force,
a piezoelectric holder fixing the piezoelectric element to the frame, and
a guide shaft having a tubular shape, fixed to the piezoelectric holder, and housing the piezoelectric element, and
the panel holder is slidably supported with respect to the guide shaft.

(4)

The light emitting device according to the above (3), wherein
the actuator includes a soft resin disposed between the piezoelectric element and the guide shaft.

(5)

The light emitting device according to any one of the above (2) to (4), wherein
a base end portion of the panel holder is narrower than a tip end portion of the panel holder.

(6)

The light emitting device according to the above (1), wherein
the actuator includes a soft magnetic material at a tip end portion, and
the substrate includes a panel holder in which a magnet is disposed at a tip end portion, and is supported by the actuator by a magnetic force acting between the magnet and the soft magnetic material.

(7)

The light emitting device according to the above (6), wherein
the actuator includes a piezoelectric element having a columnar shape and generating a vibration force, and
an abutting portion made of a resin and abutting on the piezoelectric element is provided at a position different from the magnet in the tip end portion of the panel holder.

(8)

The light emitting device according to the above (7), wherein
the abutting portion has a hemispherical shape.

(9)

The light emitting device according to any one of the above (1) to (8), wherein
the substrate includes a resin disposed between the light emitting elements adjacent to each other on the first surface, and
a surface of the light emitting element and a surface of the resin are substantially flush with each other.

(10)

The light emitting device according to any one of the above (1) to (9), wherein
a plurality of the actuators are provided between the substrate and the frame, and
all the actuators are driven in phase.

(11)

A display device comprising
a plurality of light emitting devices arranged in a matrix, wherein
the light emitting device includes
a substrate including a plurality of light emitting elements arranged on a first surface,
a frame disposed to face a second surface of the substrate opposite to the first surface, and
an actuator disposed between the substrate and the frame and vibrating the substrate, and
the substrate is configured to be detachable from the actuator.

(12)

The display device according to the above (11), wherein
the actuator includes a magnet at a tip end portion, and
the substrate includes, on the second surface, a panel holder of a soft magnetic material in contact with the magnet, and is supported by the actuator by a magnetic force acting between the magnet and the panel holder.

(13)

The display device according to the above (12), wherein
the actuator includes
a piezoelectric element having a columnar shape and generating a vibration force,
a piezoelectric holder fixing the piezoelectric element to the frame, and
a guide shaft having a tubular shape, fixed to the piezoelectric holder, and housing the piezoelectric element, and
the panel holder is slidably supported with respect to the guide shaft.

(14)

The display device according to the above (13), wherein
the actuator includes a soft resin disposed between the piezoelectric element and the guide shaft.

(15)

The display device according to any one of the above (12) to (14), wherein
a base end portion of the panel holder is narrower than a tip end portion of the panel holder.

(16)

The display device according to the above (11), wherein
the actuator includes a soft magnetic material at a tip end portion, and
the substrate includes a panel holder in which a magnet is disposed at a tip end portion, and is supported by the actuator by a magnetic force acting between the magnet and the soft magnetic material.

(17)

The display device according to the above (16), wherein
the actuator includes a piezoelectric element having a columnar shape and generating a vibration force, and
an abutting portion made of a resin and abutting on the piezoelectric element is provided at a position different from the magnet in the tip end portion of the panel holder.

(18)

The display device according to the above (17), wherein
the abutting portion has a hemispherical shape.

(19)

The display device according to any one of the above (11) to (18), wherein
the substrate includes a resin disposed between the light emitting elements adjacent to each other on the first surface, and
a surface of the light emitting element and a surface of the resin are substantially flush with each other.

(20)

The display device according to any one of the above (11) to (19), wherein
a plurality of the actuators are provided between the substrate and the frame, and
all the actuators are driven in phase.

### REFERENCE SIGNS LIST

1 SCALABLE DISPLAY (EXAMPLE OF DISPLAY DEVICE)
2 CABINET
3 LIGHT EMITTING DEVICE
10 SUBSTRATE
10a FIRST SURFACE
10b SECOND SURFACE
11 LIGHT EMITTING ELEMENT
11a SURFACE
12 PANEL HOLDER
15 RESIN
15a SURFACE
20 FRAME
30 ACTUATOR
31 PIEZOELECTRIC ELEMENT
32 MAGNET
33 PIEZOELECTRIC HOLDER
34 GUIDE SHAFT
35 SOFT RESIN
36 SOFT MAGNETIC MATERIAL
41 FIRST PORTION
42 SECOND PORTION
42a ABUTTING PORTION
43 MAGNET

1. A light emitting device comprising:
a substrate including a plurality of light emitting elements arranged on a first surface;
a frame disposed to face a second surface of the substrate opposite to the first surface; and
an actuator disposed between the substrate and the frame and vibrating the substrate, wherein
the substrate is configured to be detachable from the actuator.

2. The light emitting device according to claim 1, wherein
the actuator includes a magnet at a tip end portion, and
the substrate includes, on the second surface, a panel holder of a soft magnetic material in contact with the magnet, and is supported by the actuator by a magnetic force acting between the magnet and the panel holder.

3. The light emitting device according to claim 2, wherein
the actuator includes
a piezoelectric element having a columnar shape and generating a vibration force,
a piezoelectric holder fixing the piezoelectric element to the frame, and
a guide shaft having a tubular shape, fixed to the piezoelectric holder, and housing the piezoelectric element, and
the panel holder is slidably supported with respect to the guide shaft.

4. The light emitting device according to claim 3, wherein
the actuator includes a soft resin disposed between the piezoelectric element and the guide shaft.

5. The light emitting device according to claim 2, wherein
a base end portion of the panel holder is narrower than a tip end portion of the panel holder.

6. The light emitting device according to claim 1, wherein
the actuator includes a soft magnetic material at a tip end portion, and
the substrate includes a panel holder in which a magnet is disposed at a tip end portion, and is supported by the actuator by a magnetic force acting between the magnet and the soft magnetic material.

7. The light emitting device according to claim 6, wherein
the actuator includes a piezoelectric element having a columnar shape and generating a vibration force, and
an abutting portion made of a resin and abutting on the piezoelectric element is provided at a position different from the magnet in the tip end portion of the panel holder.

8. The light emitting device according to claim 7, wherein
the abutting portion has a hemispherical shape.

9. The light emitting device according to claim 1, wherein
the substrate includes a resin disposed between the light emitting elements adjacent to each other on the first surface, and
a surface of the light emitting element and a surface of the resin are substantially flush with each other.

10. The light emitting device according to claim 1, wherein
a plurality of the actuators are provided between the substrate and the frame, and
all the actuators are driven in phase.

11. A display device comprising
a plurality of light emitting devices arranged in a matrix, wherein
the light emitting device includes
a substrate including a plurality of light emitting elements arranged on a first surface,
a frame disposed to face a second surface of the substrate opposite to the first surface, and
an actuator disposed between the substrate and the frame and vibrating the substrate, and
the substrate is configured to be detachable from the actuator.
